(19) United States
(12) Patent Application Publication
(10) Pub. No.: US 2016/0099248 A1
(43) Pub. Date: Apr. 7, 2016

(54) SEMICONDUCTOR MEMORY DEVICE WITH IMPROVED ACTIVE AREA/WORD LINE LAYOUT

(71) Applicant: PS5 LUXCO S.A.R.L., Luxembourg (LU)

(72) Inventor: Nan Wu, Tokyo (JP)

(21) Appl. No.: 14/891,104

(22) PCT Filed: May 15, 2014
(86) PCT No.: PCT/EP2014/059966

§ 371 Date: Nov. 13, 2015

(30) Foreign Application Priority Data
May 16, 2013 (JP) 2013-104122

(51) Int. Cl. H01L 27/108; H01L 29/06; H01L 27/02; H01L 23/528

(52) U.S. Cl. CPC H01L 27/10823; H01L 27/10814; H01L 23/528; H01L 29/0649; H01L 27/0207

(57) ABSTRACT

One semiconductor device includes a bit line extending in a straight line in an X direction, a first and a second horizontal active region extending in the X direction, and a sloped active region arranged between the first and the second horizontal regions and inclined with respect to the X direction, an active region arranged at the center of a bit line impurity diffusion region, a first word line arranged in the first horizontal active region segment, a second word line arranged in the second horizontal active region segment, and a third and a fourth word line arranged in the sloped active region segment next to each other with the bit line impurity diffusion region interposed therebetween.

### TECHNICAL FIELD

The present invention relates to a semiconductor device.

### BACKGROUND

Patent Document 1 discloses a dynamic random access memory (DRAM) as one example of a semiconductor device.

In the DRAM disclosed in Patent document 1, a bit line contact is arranged in the center of a single active region surrounded by an element isolation region, and capacitors are arranged via word lines on each side, thereby sandwiching the bit line contact.

That is, two memory cells sharing a bit line contact are arranged within a single active region. Furthermore, to configure the DRAM module, single active regions are systematically aligned in the X direction and the Y directions.

Given that in this kind configuration a single bit line contact is required for each pair of memory cells, it tends to be difficult to miniaturize the entire memory cell region.

In this regard, Patents Document 2 and 3 disclose arranging a plurality of unit cells continuously in a single active region where a unit cell includes one word line and one capacitor, and arranging a single shared bit line contact at the end of the active region in what is called a cascade connected DRAM.

### Patent Documents

Patent Document 1: Japanese Unexamined Patent Application Publication No. 2012-99793

Patent Document 2: Japanese Unexamined Patent Application Publication No. H4-3463

Patent Document 3: Japanese Unexamined Patent Application Publication No. H5-152544

### SUMMARY

### Problem to be Solved by the Invention

Given that in the cascade connected DRAM disclosed in Patent Documents 2 and 3, a single bit line contact is sufficient for supporting the arrangement of a plurality of cells (for example five cells), it is possible to miniaturize the entire memory cell unit by reducing the number of bit line contacts.

However in the cascade connected DRAM disclosed in patent documents 2 and 3, the bit line contact and the plurality of cells are arranged on the active region that extends in one direction, and the capacitor is arranged under the bit line in a Capacitor Under Bit line (CUB) structure.

Therefore, when the unit cell itself is reduced in size, it tends to be difficult to ensure the capacity of the capacitor. Additionally, it tends to be difficult to read the information recorded in a cell arranged far away from the bit line contact, and thus it tends to be difficult to stably operate the DRAM.

Moreover, because the active region is arranged in a straight line, and it is necessary to angle or curve the bit line, which already requires the finest microfabrication, the result is a layout not suited for miniaturization.

### Means for Solving the Problem

A semiconductor according to an embodiment is provided with a semiconductor substrate including a bit line extending in a straight line in a first direction, an active region having a bit line impurity diffusion region arranged at the center electrically connected with the bit line; and a plurality of word lines extending in a second direction orthogonal to the first direction such that they partition the upper portion of the active region into five segments. The active region includes a first horizontal active region segment extending in the first direction and constituting one end thereof, a second horizontal active region segment extending in the first direction and constituting the other end thereof, and a sloped active region segment extending in a direction inclined with respect to the first direction and arranged between the first and the second horizontal active region segments and connecting the first and the second horizontal active region segments. The word line is arranged in each of the first and the second horizontal active region segments, and two word lines are arranged next to each other in the sloped active region segment with the bit line impurity diffusion region interposed therebetween.

### Effect of the Invention

The semiconductor device according to the present invention extends the bit line, which requires the finest microfabrication, in a straight line, and further includes two horizontal active region segments (in other words, the first and the second horizontal region segments), and a sloped active region segment arranged between the two horizontal active region segments, and thereby makes it possible to angle the active region and thus realize a layout favorable for miniaturization.

Additionally, one word line is arranged in each of the first and the second horizontal active region segments, and further arranging two word lines in the sloped active region segment next to each other such that the bit line impurity diffusion region is interposed therebetween thereby shortens the distance from the bit line impurity diffusion region to the memory cell located furthest there from.

Through this, reading of information written to the memory cell located furthest from the bit line impurity diffusion region can be easily implemented.

### BRIEF DESCRIPTION OF THE DRAWINGS

FIG. 1 is a plan view illustrating a portion of the constituent elements of a memory cell unit of a semiconductor device according to the first embodiment of the present invention.

FIG. 2 is a cross-sectional view along the line A-A of the memory cell unit of the semiconductor device illustrated in FIG. 1.

FIG. 3 is an equivalent circuit diagram of a memory cell unit of the semiconductor device (DRAM) disclosed in Patent Document 1.

FIG. 4 is an equivalent circuit diagram of a memory cell unit of the semiconductor device according to the first embodiment of the present invention.

FIG. 5 is a plan view illustrating a portion of the constituent elements of a memory cell unit of a semiconductor device according to a second embodiment of the present invention.

FIG. 6 is a plan view illustrating a portion of the constituent elements of a memory cell unit of a semiconductor device according to a third embodiment of the present invention.

FIG. 7 is a cross-sectional view along the line H-H of the memory cell unit of the semiconductor device illustrated in FIG. 6.

### DESCRIPTION OF THE PREFERRED EMBODIMENTS

Embodiments of the present invention will be described in detail below with reference to the drawings. In some cases, the drawings used in the following description include enlarged views of certain features, however this is merely for illustrative purposes to aid understanding and should not be interpreted as dictating the proportional dimensions and so forth of the constituent elements.

Furthermore, the materials, dimensions, and the like mentioned in the following description are merely examples, and the present invention is not limited thereto; the materials, dimensions, and and the like mentioned may be modified insofar as the modifications do not exceed the spirit and scope of the present invention.

### First Embodiment

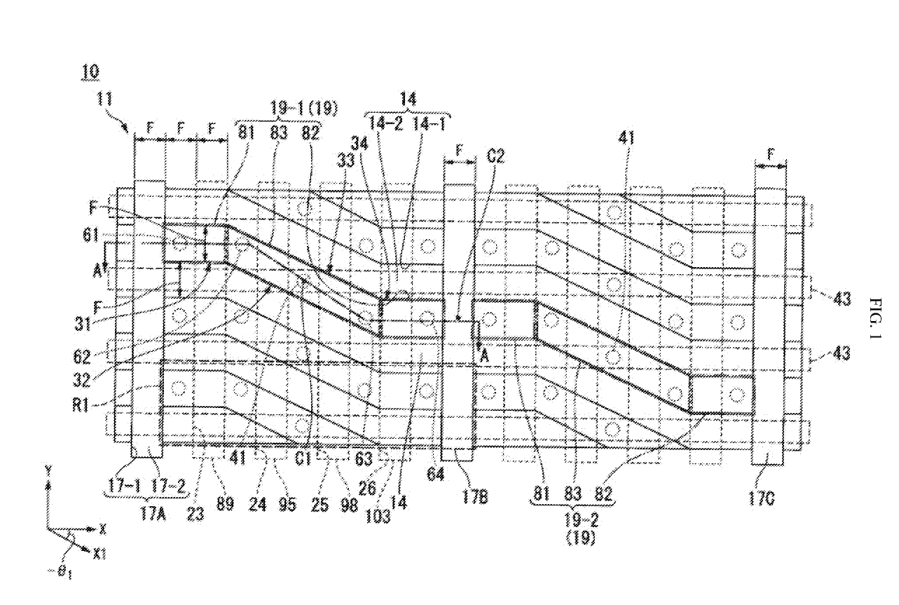

FIG. 1 is a plan view illustrating a portion of the constituent elements of a memory cell unit of a semiconductor device according to a first embodiment of the present invention.

Among the constituent elements of a memory cell unit 11, FIG. 1 shows only a first element isolation region 14, second element isolation regions 17A to 17C, active regions 19, 19-1, and 19-2 (unitary active regions), first through fourth trenches 23 to 26, first through fourth transistors 31 to 34, a bit line contact plug 41, a bit line 43, first through fourth capacitor contact plugs 61 to 64, a first horizontal active region segment 81, a second horizontal active region segment 82, a sloped active region segment 83, and first through fourth word lines 89, 95, 98, 103. All other constituent elements thereof are omitted from the illustration.

In FIG. 1, the X direction (a first direction) is the direction in which the bit line 43 extends, and the Y direction (a second direction) is the direction in which second element isolation regions 17A to 17C, and the first through fourth word lines 89, 95, 98, and 103 extend; the X1 direction, which is orthogonal to the X direction, is the direction of extension of the sloped active region segment 83, which constitutes the active regions 19, 19-1, and 19-2. The angle formed between the X direction, and the X1 direction is −θ₁.

Additionally, the region defined by R1 shown in FIG. 1 represents a basic cell region (referred to as “basic cell region R1”) that includes four memory cells MC1 to MC4, and one bit line impurity diffusion region 96.

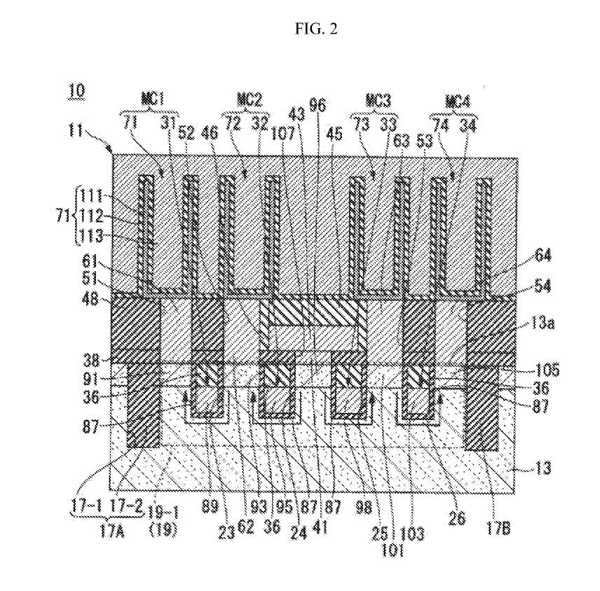

FIG. 2 is a cross-sectional view along the line A-A in the memory cell unit of the semiconductor device illustrated in FIG. 1. In FIG. 2, sections having the same configuration as the memory cell unit 11 of the semiconductor device 10 illustrated in FIG. 1 are given the same reference numerals. Furthermore, in FIG. 2 the region in which the channels for the first through fourth transistors 31 to 34 are formed are indicated by solid arrows.

FIG. 1 and FIG. 2 show a Dynamic Random Access Memory (DRAM) module as one example of the semiconductor device 10 of the first embodiment, which will be described below.

As illustrated in FIG. 1 and FIG. 2, the semiconductor device 10 of the first embodiment includes a memory cell unit 11 provided in a memory cell region, and peripheral circuitry (not shown) provided in a peripheral circuitry region (not shown) surrounding the memory cell unit 11.

The peripheral circuitry (not shown) includes circuits (including transistors used in the peripheral circuitry not shown) for controlling the operation of a plurality of memory cells MC1 to MC4 arranged in the memory cell unit 11.

The memory cell unit 11 constituting the semiconductor device 10 of the first embodiment will be mainly described below.

The memory cell unit 11 includes a semiconductor substrate 13, a first element isolation region 14 (other element isolation region), second element isolation regions 17A to 17C (element isolation region), an active region 19, first through fourth trenches 23 to 26, first through fourth transistors 31 to 34, embedding insulating film 36, an interlayer insulating film 38 for bit line contact formation, a bit line contact plug 41, a bit line 43, a cap insulating film 45, a sidewall 46, an interlayer insulating film 48 for capacitor contact formation, a first capacitor contact hole 51, a second capacitor contact hole 52, a third capacitor contact hole 53, a fourth capacitor contact hole 54, a first capacitor contact plug 61, a second capacitor contact plug 62, a third capacitor contact plug 63, a fourth capacitor contact plug 64, a first capacitor 71, a second capacitor 72, a third capacitor 73, a fourth capacitor 74, a first memory cell MC1, a second memory cell MC2, a third memory cell MC3, and a fourth memory cell MC4.

The semiconductor substrate 13 is a flat sheet-like substrate. The body of the semiconductor substrate 13 may be a p-type monocrystalline silicon substrate.

In the following explanation, the p-type monocrystalline silicon substrate used for the semiconductor substrate 13 will be described.

The first element isolation region 14 is embedded in the main surface 13a of the semiconductor substrate 13. The first element isolation region 14 is structured so that a section extending in the X direction, and a section extending in the X1 direction are repeatedly arranged one after the other. Thus the first element isolation region 14 meanders in the X1 direction while extending in the X direction. A plurality of first element isolation regions 14 is arranged in the Y direction with a predetermined interval therebetween.

In the Y direction, the plurality of first element isolation regions 14 are compartmentalized between the active regions 19 arranged in the Y direction.

The width of the first element isolation region 14 in the Y direction may be, for example, a minimum fabrication dimension F, which is the limit resolution of photolithographic technology (referred to below as only as simply “minimum fabrication dimension F”).

The first element isolation region 14 is formed in the main surface 13a of the semiconductor substrate 13, and includes a first element isolation trench 14-1 which extends in the X direction while meandering in the X1 direction, and a first element isolation insulating film 14-2 which is, for example, a silicon oxide (SiO₂) film, or a silicon nitride (SiN) film, embedded in the first element isolation trench 14-1.

The second element isolation regions 17A to 17C are provided in the main surface 13a of the semiconductor substrate 13 such that they extend in the Y direction. The second element isolation regions 17A to 17C are repeatedly arranged in the X direction in the order from the second element isolation region 17A, the second element isolation region 17B, and the second element isolation region 17C. The second element isolation regions 17A to 17C partition the plurality of first element isolation regions 14 arranged in the Y direction.

The second element isolation region 17A includes a second element isolation trench 17-1 extending in the Y direction, and a second element isolation insulating film 17-2 which is, for example, composed of a silicon oxide (SiO₂) film, or a silicon nitride (SiN) film, embedded in the second element isolation trench 17-1. The second element isolation regions 17B and 17C have the same configuration as the second element isolation region 17A.

The second element isolation region 17B is in contact with two active regions 19 in the X direction; more specifically, the second element isolation region 17B is in contact with the later described second horizontal region segment 82 of the active region 19-1, and the first horizontal active region 81 of the active region 19-2.

The width of the second element isolation regions 17A to 17C may be, for example the minimum fabrication dimension F. The depth of the first and the second element isolation regions 14 and 17A to 17C from the main surface 13a of the semiconductor substrate 13 may be 250 nm, for example.

The active region 19 is configured by the semiconductor substrate 13, which is compartmentalized by the two first element isolation regions 14 arranged side by side and the second element isolation regions 17A and 17B, or by the semiconductor substrate 13, which is compartmentalized by the two first element isolation regions 14 arranged side by side and the second element isolation regions 17B and 17C.

In the first embodiment, for the purpose of illustration, in the description that follows the active region 19 compartmentalized by the two first element isolation regions 14 arranged side by side and the second element isolation regions 17A and 17B will be referred to as the active region 19-1 (one active region); and the active region 19 arranged next to an active region 19-1 in the X1 direction and compartmentalized by the two first element isolation regions 14 arranged side by side and the second element isolation regions 17A and 17B will be referred to as the active region 19-2 (another active region).

The active regions 19-1 and 19-2 are systematically aligned with a spacing there between in the Y direction being the minimum fabrication size F, and with a layout pitch of 2F (two times the minimum fabrication dimension).

The end of the active region 19-1 in the X direction is defined by the second element isolation regions 17A and 17B. The end of the active region 19-2 in the X direction is defined by the second element isolation regions 17B and 17C.

The active regions 19-1 and 19-2 have a section extending in the X direction, and a section extending in the X1 direction and also have a bent shape. On the whole, the active regions 19-1 and 19-2 are systematically aligned in the X1 direction.

The configuration of the active region 19-1 will be described herein. The active region 19-1 is equally divided into five segments by the first through fourth word lines 89, 95, 98, and 103 (the plurality of word lines) extending above the active region 19-1 in the Y direction, and the active region 19-1 includes a first horizontal active region segment 81, a second horizontal active region segment 82, and a sloped active region segment 83.

The first horizontal active region segment 81 extends in the X direction and constitutes one end portion of the active region 19-1. The first horizontal active region segment 81 is in contact with the second element isolation region 17A. In a plan view, the first horizontal active region segment 81 is a square with the width in the Y direction equal to the minimum fabrication dimension F.

The second horizontal active region segment 82 extends in the X direction and constitutes the other end portion of the active region 19-1. The second horizontal active region segment 82 is in contact with the second element-isolation region 17B. In a plan view, the second horizontal active region segment 82 is a square with the width in the Y direction equal to the minimum fabrication dimension F.

The widths of the first and the second horizontal active region segment 81 and 82 may be made the same size in the X direction. More specifically, the widths of the first and the second horizontal active region segments 81 and 82 in the X direction may be, for example, 2F (two times the minimum of fabrication dimension).

The first and second horizontal active region segments 81 and 82 are arranged in the Y direction on both sides of a bit line 43 (a bit line extending in a straight line), which passes above the bit line impurity diffusion region 96 arranged at the center of the active region 19-1.

The sloped active region segment 83 extends in the X1 direction, which is inclined with respect to the X direction, and is arranged between the first and second horizontal active region segments 81 and 82 and connects the first and second horizontal active region segments 81 and 82. Both ends of the sloped active region segment 83 are integrated with the first and second horizontal active region segments 81 and 82. In plan view, the sloped active region segment 83 is a parallelogram.

Of the sloped active region segment 83, the portion that is positioned between the second and third trenches 24 and 25 becomes the central section of the sloped active region segment 83 (in other words, the center of the active region 19-1) where the bit line impurity diffusion region 96, which is electrically connected to the bit line 43, is arranged.

The active region 19-1 configured in the above manner is formed so as to be symmetrical about a central point C1 located at the center of the central section of the sloped active region segment 83.

As with the active region 19-1, the active region 19-2 includes a first horizontal active region segment 81, a second horizontal active region segment 82, and a sloped active region segment 83.

The first horizontal active region segment 81 of the active region 19-2 sandwiches the second element-isolation region 17B and is arranged to face the second horizontal active region segment 82 of the active region 19-1. The first horizontal active region segment 81 of the active region 19-2 is in contact with the second element isolation region 17B.

The active regions 19-1 and 19-2 are arranged so as to be symmetrical about a center point C2 of a section sandwiched by the first and the second horizontal active region segments 81 and 82 of the second element isolation region 17B.

As described above, with the exception of being compartmentalized by the second element isolation regions 17B and 17C in the X direction, the active region 19-2 has the same configuration as the active region 19-1; more specifically, the active region 19-2 has the same shape, and is configured by the same material, and therefore an explanation will be given of mainly the active region 19-1.

The first through fourth trenches 23 to 26 extend in the Y direction and are arranged in the active region 19-1 so as to divide the active region 19-1 into five equal segments.

The first trench 23 is provided in the first horizontal active region segment 81. The second and third trenches 24 and 25 are provided in the sloped active region segment 83. The second and third trenches 24 and 25 define both ends of the central section (the section including the bit line impurity diffusion region 96) of the sloped active region segment 83 in the X direction. The fourth trench 26 is provided in the second horizontal active region segment 82.

That is, the first through fourth trenches 23 to 26 are arranged in the order of the first trench 23, the second trench 24, the third trench 25, and the fourth trench 26 from the second element isolation region 17A in a direction toward the second element isolation region 17B.

The first through fourth trenches 23 to 26 partition the plurality of first element isolation regions 14 arranged in the Y direction.

The depth of the first through fourth trenches 23 to 26 from the main surface 13a of the semiconductor substrate 13 may be shallower than the depth of the first and the second element isolation regions 14, and 17A to 17C.

If the depth of the first and the second element isolation regions 14, and 17A to 17C is 250 nm, then the depth of the first through fourth trenches 23 to 26 may be, for example, 150 nm.

The first through fourth transistors 31 to 34 are selective transistors (select transistors) and are provided in one active region 19-1.

The first transistor 31 includes a gate insulating film 87, a first word line 89, a first capacitor impurity diffusion region 91, and a second capacitor impurity diffusion region 87.

The gate insulating film 87 is arranged to as to cover the inner surface of the first trench 23. For example, a single layer of silicon oxide film (SiO₂ film), a nitrided silicon oxide film (SiON film), a laminated silicon oxide film (SiO₂ film), a laminated film obtained by laminating silicon nitride film (SiN film) on top of silicon oxide film (SiO₂ film), and the like may be used for the gate insulating film 87.

The first word line 89 is arranged so to be embedded in the lower portion of the first trench 23 via the gate insulating film 87. The first word line 89 functions as a gate electrode for the first transistor 31. In other words, the gate electrode (the first word line 89) for the first transistor 31 is an embedded gate electrode provided inside the first horizontal active region segment 81.

The first word line 89 extends in the Y direction, and functions as a gate electrode shared among the plurality of first transistors 31 arranged along the Y direction.

For instance, a metal film or polycrystalline silicon film and so forth may be used for the conductive film constituting the first word line 89. For example, titanium nitride film (TiN film), and tungsten film (W film) may be laminated in that order to create a laminated film which may be used as the metal film constituting the first word line 89.

The first capacitor impurity diffusion region 91 is arranged in the active region 19-1, which is located between the upper portion of the second element isolation region 17A adjoining the first trench 23, and the upper portion of the first trench 23, and more specifically in the first horizontal active region segment 81.

The upper surface of the first capacitor impurity diffusion region 91 coincides with the main surface 13a of the semiconductor substrate 13. The depth of the first capacitor impurity diffusion region 91 from the main surface 13a of the semiconductor substrate 13 may be, for example, 50 nm.

The second capacitor impurity diffusion region 93 is arranged in the active region 19-1, which is located between the upper portion of the first trench 23, and the upper portion of the second trench 24, and more specifically in the sloped active region segment 83.

The upper surface of the second capacitor impurity diffusion region 93 coincides with the main surface 13a of the semiconductor substrate 13. The depth of the second capacitor impurity diffusion region 93 from the main surface 13a of the semiconductor substrate 13 may be, for example, 50 nm.

When the semiconductor substrate 13 is a p-type monocrystalline silicon substrate, an n-type impurity diffusion region formed by implanting n-type impurities into the p-type monocrystalline substrate may be used for the first and the second capacitor impurity diffusion regions 91 and 93.

The second transistor 32 includes the gate insulating film 87, the second word line 95, the second capacitor impurity diffusion region 93, and the bit line impurity diffusion region 96.

The gate insulating film 87 is arranged so as to cover the inner surface of the second trench 24, and the second word line 95 is arranged so as to be embedded in the lower portion of the second trench 24 via the gate insulating film 87. The second word line 95 extends in the Y direction, and functions as a gate electrode for the second transistor 32.

In other words, the gate electrode (the second word line 95) for the second transistor 32 is an embedded gate electrode provided inside the sloped active region segment 83.

The second word line 95 functions as a gate electrode shared among the plurality of second transistors 32 arranged along the Y direction. For example, as a conductive film that configures the second word line 95, a film-forming conductive film can be used as the base material when forming the first word line 89.

The bit line impurity diffusion region 96 is arranged in the center of the active region 19-1 located between the upper portion of the second trench 24 and the upper portion of the third trench 25, and more specifically in center section of the sloped active region segment 83.

The upper surface of the bit line impurity diffusion region 96 coincides with the main surface 13a of the semiconductor substrate 13. The depth of the bit line impurity diffusion region 96 from the main surface 13a of the semiconductor substrate 13 may be, for example, 50 nm.

When the semiconductor substrate 13 is a p-type monocrystalline silicon substrate, an n-type impurity diffusion region formed by ion implanting n-type impurities into the p-type monocrystalline substrate may be used for the bit line impurity diffusion region 96.

The third transistor 33 includes the gate insulating film 87, the third word line 98, the bit line impurity diffusion region 96, and a third capacitor impurity diffusion region 101.

The gate insulating film 87 is arranged so as to cover the inner surface of the third trench 25. The third word line 98 is arranged so to be embedded in the lower portion of the third trench 25 via the gate insulating film 87. The third word line 98 extends in the Y direction, and functions as a gate electrode for the third transistor 33.

In other words, the gate electrode (the third word line 98) for the third transistor 33 is an embedded gate electrode provided inside the second horizontal active region segment 82.

The third word line 98 functions as a gate electrode shared among the plurality of third transistors 33 arranged along the Y direction. For example, as a conductive film that configures the third word line 98, a film-forming conductive film can be used as the base material when forming the first word line 89.

The third capacitor impurity diffusion region 101 is arranged in the active region 19-1 located between the upper portion of the third trench 25, and upper portion of the fourth trench 26, and more specifically in the second horizontal active region segment 82.

The upper surface of the third capacitor impurity diffusion region 101 coincides with the main surface 13a of the semiconductor substrate 13. The depth of the third capacitor impurity diffusion region 101 from the main surface 13a of the semiconductor substrate 13 may be, for example, 50 nm.

When the semiconductor substrate 13 is a p-type monocrystalline silicon substrate, an n-type impurity diffusion region produced by ion implanting n-type impurities into the p-type monocrystalline substrate may be used for the third capacitor impurity diffusion region 101.

The fourth transistor 34 includes the gate insulating film 87, the fourth word line 103, the third capacitor impurity diffusion region 101, and a fourth capacitor impurity diffusion region 105.

The gate insulating film 87 is arranged so as to cover the inner surface of the fourth trench 26, and the fourth word line 103 is arranged so as to be embedded in the lower portion of the fourth trench 26 via the gate insulating film 87.

In other words, the gate electrode (the fourth word line 103) for the fourth transistor 34 is provided in the sloped active region segment 83 at a location between the bit line impurity diffusion region 96 and the second horizontal active region segment 82.

The fourth word line 103 extends in the Y direction, and functions as a gate electrode for the fourth transistor 34. The fourth word line 103 extends in the Y direction, and functions as a gate electrode shared among the plurality of fourth transistors 34 arranged along the Y direction.

For example, as a conductive film that configures the fourth word line 103, a film-forming conductive film can be used as the base material when forming the first word line 89.

The fourth capacitor impurity diffusion region 105 is arranged in the active region 19 located between the upper portion of the fourth trench 26, and the upper portion of the second element-isolation region 17B.

The upper surface of the fourth capacitor impurity diffusion region 105 coincides with the main surface 13a of the semiconductor substrate 13. The depth of the fourth capacitor impurity diffusion region 105 from the main surface 13a of the semiconductor substrate 13 may be, for example, 50 nm.

When the semiconductor substrate 13 is a p-type monocrystalline silicon substrate, and n-type impurity diffusion region produced by ion implanting n-type impurities into the p-type monocrystalline substrate may be used for the fourth capacitor impurity diffusion region 105.

The above described first through fourth transistors 31 to 34 are structured such that the first through fourth word lines 89, 95, 98, and 103 (gate electrodes) are embedded in the semiconductor substrate 13, therefore forming three dimensional channel regions (the regions corresponding to the solid arrows shown in FIG. 2) in the semiconductor substrate 13 configuring the bottom and sides surfaces of the first through fourth trenches 23 to 26 in the active region 19-1.

In this manner, the channel regions formed by the first through fourth transistors 31 to 34 are formed three dimensionally, and thereby make it possible to increase the effective channel length thereof compared to the well-known planar transistor, and to prevent the short channel effect.

Additionally, preventing the short channel effect thereby allows for further advances in the microfabrication of the first through fourth transistors 31 to 34.

As above described, the first through fourth word lines 89, 95, 98, and 103 are arranged inside the first through fourth trenches 23 to 26, and therefore partition the upper portion of the active region 19-1 into five equal segments.

Additionally, the second and third word lines 95 and 98 are arranged next to each other with the bit line impurity diffusion region 96 interposed therebetween.

The embedding insulation film 36 is arranged to embed the first through fourth trenches 23 to 26 via the gate insulating film 87. Hereby, the embedding insulating film 36 covers the upper surface of the first through fourth word lines 89, 95, 98, and 103. The upper surface of the embedded insulation film 36 is flush with the main surface 13a of the semiconductor substrate 13.

As the embedding insulating film 36, a silicon nitride film (SiN film), for example, may be used.

The interlayer insulating film 38 for bit line contact formation is provided on the upper surface of the first element isolation region 14, the upper surface of the embedding insulating film 36, and the upper surface of the second element insulation isolation regions 17A to 17C. The interlayer insulating film 38 for bit line contact formation for bit line contact formation includes a bit line contact opening 107 that exposes the upper surface of the bit line impurity diffusion region 96.

The bit line contact plug 41 is provided embedded in the bit line contact opening 107. Hereby, the lower end of the bit line contact plug 41 is in contact with the upper surface of the bit line impurity diffusion region 96.

The bit line contact plug 41 may be constituted by, for example, a polysilicon film doped with impurities, a metal film, or the like. For instance, a titanium silicide film (for example, TiSi₂ film), a titanium nitride film (TiN film), and tungsten film (W film), and so forth may be use as the metal film.

The bit line 43 extends in a straight line in the X direction and then passes above the center point C1 of the sloped active region segment 83 on the semiconductor substrate 13, and more specifically on the bit line contact plug 41 and on the interlayer insulating film 38 for bit line contact formation. A plurality of bit lines 43 is arranged in the Y direction with a predetermined interval therebetween.

The bit lines 43 are integrated with the upper ends of the plurality of bit line contact plugs 41 arranged in the X direction.

Hereby the bit lines 43 are electrically connected to the plurality of bit line contact plugs 41 arranged in the X direction and are electrically connected to the bit line impurity diffusion region 96 via the bit line contact plugs 41.

As the conductive film constituting the bit line 43, a laminated film creating by laminating in order a titanium nitride film and a tungstem film, or a titanium nitride film or the like may be used for example.

The cap insulating film 45 is provided to cover the upper surface of the bit line 43. The cap insulating film 45 protects the upper surface of the bit line 43, and functions as an etching mask when patterning the insulating film employed as the base material when forming the bit line 43 using anisotropic dry etching.

For instance, a silicon nitride film (SiN film) may be used as the base material for the cap insulating film 45.

The sidewall 46 covers the side surface of the bit line 43, and the side surface of the cap insulating film 45, and for example, a silicon nitride film (SiN film) may be employed as the base material for the sidewall 46.

The interlayer insulating film 48 for capacitor contact formation is provided on the interlayer insulating film 38 for bit line contact formation such that it is buried in the space created between the bit lines 43 via the sidewall 46. The upper surface of the interlayer insulating film 48 for capacitor contact formation is flush with the upper surface of the cap insulating film 45.

The interlayer insulating film 48 for capacitor contact formation may be a silicon oxide film (SiO₂) formed by chemical vapor deposition (CVD), or a coated insulating film (silicon oxide film, SiO₂) formed using the spin on glass (SOG) technique.

The first capacitor contact hole 51 is provided in the interlayer insulating film 48 for capacitor contact formation to expose the upper surface of the first capacitor impurity diffusion region 91. The second capacitor contact hole 52 is provided in the interlayer insulating film 48 for capacitor contact formation to expose the upper surface of the second capacitor impurity diffusion region 93.

The third capacitor contact hole 53 is provided in the interlayer insulating film 48 for capacitor contact formation to expose the upper surface of the third capacitor impurity diffusion region 101. The fourth capacitor contact hole 54 is provided in the interlayer insulating film 48 for capacitor contact formation to expose the upper surface of the fourth capacitor impurity diffusion region 105.

The first capacitor contact plug 61 is provided embedded in the first capacitor contact hole 51. The lower end of the first capacitor contact plug 61 is therefore in contact with the upper surface of the first capacitor impurity diffusion region 91.

The second capacitor contact plug 62 is provided embedded in the second capacitor contact hole 52. The lower end of the second capacitor contact plug 62 is therefore in contact with the upper surface of the second capacitor impurity diffusion region 93.

The third capacitor contact plug 63 is provided embedded in the third capacitor contact hole 53. The lower end of the third capacitor contact plug 63 is therefore in contact with the upper surface of the third capacitor impurity diffusion region 101.

The fourth capacitor contact plug 64 is provided embedded in the fourth capacitor contact hole 54. The lower end of the fourth capacitor contact plug 64 is therefore in contact with the upper surface of the fourth capacitor impurity diffusion region 105.

The upper end surfaces of the above-mentioned first through fourth capacitor contact plugs 61 to 64 are arranged further above the upper surface of the bit lines 43. Hereby, a COB (Capcitor Over Bit Line) structure may be achieved with the capacitors (any of one of the first through fourth capacitors 71 to 74), which are arranged on the upper end surface of the first through fourth capacitor contact plugs 61 to 64, arranged further upward than the bit lines 43.

Through this, compared to a structure where the capacitors are arranged below the bit lines 43, it is possible to increase the capacitance of the above-mentioned capacitors arranged above the first through fourth capacitor contact plugs 61 to 64.

The first capacitor 71 includes a lower electrode 111, a capacitor insulation film 112, and an upper electrode 113. The lower electrode 111 is crown shaped, and the lower electrode 111 is arranged on the interlayer insulating film 48 for capacitor contact formation, and is connected to the upper end of the first capacitor contact plug 61.

Hereby, the lower electrode 111 is electrically connected to the first capacitor impurity diffusion region 91 via the first capacitor contact plug 61.

The capacitor insulation film 112 is arranged so as to cover the surface of the lower electrode 111. The capacitor insulation film 112 is of a thickness that does not embed the inner portions of the lower electrode 111.

The upper electrode 113 is arranged so as to cover the surface of the capacitor insulation film 112. The upper electrode 113 is of a thickness such that the inside of the lower electrodes 111 and the space formed between the lower electrodes 111 are not embedded via the capacitor insulation film 112. The upper surface of the upper electrode 113 is flat.

The second through fourth capacitors 72 to 74 have the same configuration as the first capacitor 71 except that arrangement positions of the lower electrodes 111 differ from the arrangement positions of the first capacitor 71.

The lower electrode 111 of the second capacitor 72 is arranged on the upper end of the second capacitor contact plug 62. Hereby, the second capacitor 72 is electrically connected to the second capacitor impurity diffusion region 93 via the second capacitor contact plug 62.

The lower electrode 111 of the third capacitor 73 is arranged on the upper end of the third capacitor contact plug 63. Hereby, the third capacitor 73 is electrically connected to the third capacitor impurity diffusion region 101 via the third capacitor contact plug 63.

The lower electrode 111 of the fourth capacitor 74 is arranged on the upper end of the fourth capacitor contact plug 64. Hereby, the fourth capacitor 74 is electrically connected to the fourth capacitor impurity diffusion region 105 via the fourth capacitor contact plug 64.

The first memory cell MC1 is constituted by a first transistor 31, and a first capacitor 71. The second memory cell MC2 is constituted by a second transistor 32, and a second capacitor 72.

The third memory cell MC3 is constituted by a third transistor 33, and a third capacitor 73. The fourth memory cell MC4 is constituted by a fourth transistor 34, and a fourth capacitor 74.

That is, the first memory cell MC1, the second memory cell MC2 are arranged continuously within the sloped active region segment 83 which extends toward one side (the second element isolation region 17A side) of the bit line impurity diffusion region 96 arranged in the center of the active region 19-1, and within the first horizontal active region segment 81 without the bit line impurity diffusion region 96 interposed therebetween.

Additionally, the third memory cell MC3, and the fourth memory cell MC4 are arranged continuously within the sloped active region segment 83, which extends toward the other side (the second element isolation region 17B) of the bit line impurity diffusion region 96 arranged in the center of the active region 19-1, and within the second horizontal active region segment 82 without the bit line impurity diffusion region 96 interposed therebetween.

If, in the above configured semiconductor device 10, the respective widths of the second element isolation regions 17A to 17C in the X direction, the widths of the first through fourth capacitive impurity diffusion regions 91, 93, 101, and 105 in the X direction, the width of the bit line impurity diffusion region 96 in the X direction, the widths of the first through fourth word lines 89, 95, 98, and 103 in the X direction, the width of the first element isolation region 14 in the Y direction, and the width of the active region 19-1 in the Y direction are the minimum fabrication dimension F, then the respective widths of the first horizontal active region segment 81 in the X direction and the second horizontal active region segment 81 in the X direction are 2F, and the width of the slope active region segment 83 in the X direction is 5F.

Accordingly, the total width of the first through fourth capacitor impurity diffusion regions 91, 93, 101, and 105, the bit line impurity diffusion region 96, the first through fourth word lines 89, 95, 98, and 103, and the second element isolation region 17B is 10F.

That is, the width of a basic cell region R1 including the four memory cells MC1 to MC4 and a single bit line impurity diffusion region 96 in the X direction is 10F, and in the Y direction is 2F. Accordingly, the area of the basic cell region R1 is 20F².

Therefore, the area of one memory cell is 5F². If the memory cell disclosed in Patent Document 3 has a width of each constituent element of F, then the area of a single cell is 6F²; however adopting the structure of the semiconductor device 10 of the first embodiment reduces the size of the memory cell compared to the memory cell disclosed in Patent Document 3.

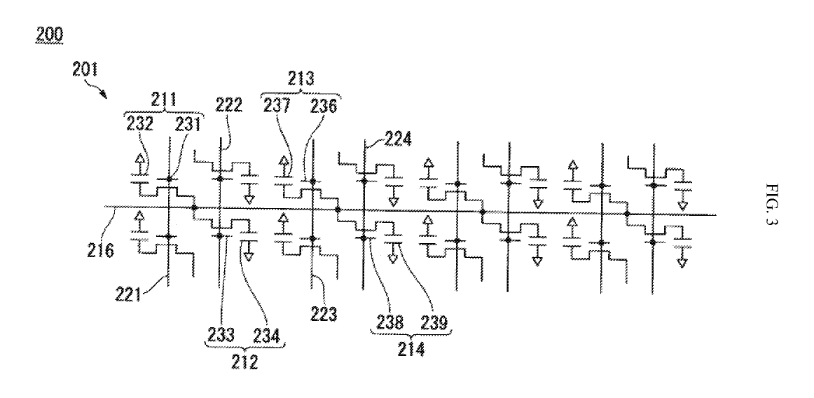

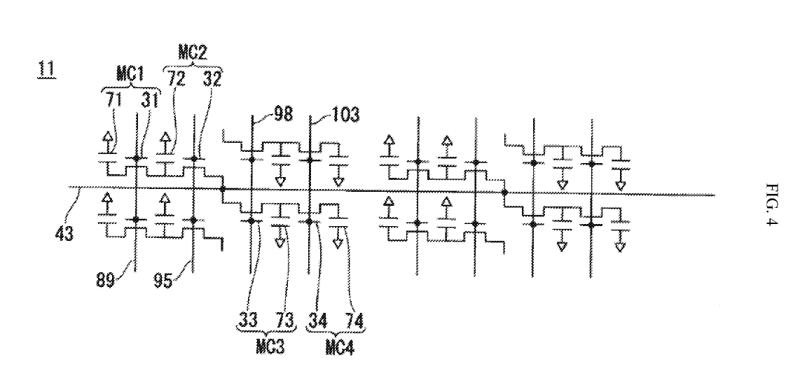

FIG. 3 is an equivalent circuit diagram of a memory cell unit in the semiconductor device (DRAM) disclosed in Patent Document 1. FIG. 4 is an equivalent circuit diagram of a memory cell unit in the semiconductor device according to the first embodiment. Sections having the same configuration as the memory cell unit 11 in the semiconductor device 10 illustrated in FIGS. 1 and 2 are given the same reference numerals in FIG. 4.

Referring to FIG. 3, a single memory cell is arranged on each side of a bit line impurity diffusion region (not shown) arranged at the center of the active region (not shown) in a memory cell unit 201 of a conventional semiconductor device 200 disclosed in Patent Document 1.

More specifically, a first memory cell 211 made from a first transistor 231 and a first capacitor 232 is arranged on one side of the bit line impurity diffusion region, and a second memory cell 212 made from a second transistor 233 and a second capacitor 234 is arranged on the other side of the bit line impurity diffusion region.

Additionally, a third memory cell 213 made from a third transistor 236 and a third capacitor 237 is arranged on one side of a bit line impurity diffusion region that differs from the above bit line impurity diffusion region, and a a fourth memory cell 214 made from a fourth transistor 238 and a fourth capacitor 239 is arranged on the other side of the different bit line impurity diffusion region.

The configuration is such that both of the memory cells are directly connected to a bit line 216.

A first word line 221 is a component of the first transistor 231 while a second word line 222 is a component of the second transistor 233.

A third word line 223 is a component of the third transistor 236 while a fourth word line 224 is a component of the fourth transistor 238.

Whereas, referring to FIG. 1, FIG. 2, and FIG. 4, two memory cells (more specifically, the first and the second memory cell MC1 and MC2) are arranged continuously on one side of the bit line impurity diffusion region 96 arranged at the center of the active region 19-1; furthermore, two memory cells (more specifically, the third and the fourth memory cells MC3 and MC4) are arranged continuously on the other side of the bit line impurity diffusion region 96 in the memory cell unit 11 in the semiconductor device 10 according to the first embodiment.

In the memory cell unit 11 with the above-described configuration, the operations of the first and second memory cells MC1 and MC2, which are arranged on one side of the bit line impurity diffusion region 96 are implemented as hereinafter described.

When reading the information written to the second memory cell MC2, the second transistor 32 arranged next to the bit line impurity diffusion region 96 is on.

More specifically, a prescribed positive voltage is applied to the second word line 95 to create a channel region to thereby read the information stored in the second capacitor 72 into the bit line 43.

Next, when reading the information written to the first memory cell MC1, the first transistor 31 is turned on while the second transistor 32 is kept in the on state.

More specifically, a prescribed positive voltage is applied to the first word line 89 to create a channel region and to thereby read the information stored in the first capacitor 71 into the bit line 43 via the second transistor 32.

Whereas, when writing information, both the first and the second transistors 31 and 32 are kept on while an electrical potential corresponding to the information to be written is applied to the bit line 43 to thereby store the information in the first capacitor 71.

The first transistor 31 is turned off when the information is stored in the first capacitor 71. Subsequently, while the first and the second transistors 31 and 32 are on, an electrical potential corresponding to the information to be written is applied to the bit line 43 to thereby store information in the second capacitor 72.

In this manner, independent pieces of information may be written to the first memory cell MC1, and the second memory cell MC2. That is, the read operation is performed in order from the memory cell closest to the bit line 43 to the memory cell furthest from the bit line 43, and the write operation is performed in order from the memory cell furthest from the bit line 43 to the memory cell closest to the bit line 43.

The semiconductor device 10 of the first embodiment configured as above described is provided with a semiconductor substrate 13 including a bit line 43 extending in a straight line in the X direction, an active region 19-1 having a bit line impurity diffusion region 96 arranged at the center thereof with the bit line impurity diffusion region 96 connected to one bit line contact plug 41 that is connected to the bit line 43; and first through fourth word lines 89, 95, 98, and 103 extending in the Y direction orthogonal to the X direction so as to partition the upper portion of the active region 19-1 into five segments. The active region 19-1 includes a first horizontal active region segment 81 extending in the X direction and constituting one end thereof, and a second horizontal active region segment 82 extending in the X direction and constituting the other end thereof, and a sloped active region segment 83 extending in a direction inclined with respect to the X direction and arranged between the first and the second horizontal active region segments 81 and 82 and connecting the first and the second horizontal active region segments. The first word line 89 is arranged in the first horizontal active region segment 81, the second and third word lines 95 and 98 are arranged next to each other with the bit line impurity diffusion region 96 interposed therebetween, and the fourth word line 103 is arranged in the second horizontal active region segment 82.

The semiconductor device 10 according to the first embodiment extends the bit line 43, which requires the finest microfabrication, in a straight line, and further includes the first horizontal active region segment 81, the second horizontal active region segment 82, and the sloped active region segment 83 arranged between the first and the second horizontal active region segments 81 and 82 in the active region 19-1, thereby making it possible to angle the active region 19-1 and thus realize a layout favorable for miniaturization.

Additionally, word lines, more specifically the first and second word lines 89 and 95, are arranged one each in the first and the second horizontal active region segments 81 and 82, and two word lines, specifically the third and fourth word lines 98 and 103, are arranged next to each other in the sloped active region segment 83 with the bit line impurity diffusion region 96 interposed therebetween, and as a result, the distance from the bit line impurity diffusion region 96 to the memory cell located furthest therefrom (in this case, the first and fourth memory cells MC1, MC4) can be shortened.

This layout facilitates reading information written to the memory cell located furthest from the bit line impurity diffusion region 96.

Moreover, an interlayer insulation film (not shown), a via part (not shown) that penetrates the interlayer insulation film, wiring (not shown) arranged on the interlayer insulation film and electrically connected with the via part, and the like may be provided on the upper surface of the upper electrode 113 illustrated in FIG. 2.

Next, a method of manufacturing the semiconductor device 10 of the first embodiment, and more specifically the memory cell unit 11, will be described while referring to FIG. 1 and FIG. 2.

First, a p-type monocrystalline silicon substrate is prepared as the semiconductor substrate 13. Thereafter, the first element isolation region 14 is formed mutually extending in the X direction and the X1 direction in the main surface 13a of the semiconductor substrate 13 using known methods such as shallow trench isolation (STI).

A plurality of first element isolation regions 14 is arranged in the Y direction with a predetermined interval therebetween. The upper surface of the plurality of first element isolation regions 14 is formed flush with the main surface 13a of the semiconductor substrate 13. The depth of the first element isolation region 14 from the main surface 13a of the semiconductor substrate 13 may be 250 nm, for example.

The width of a first element isolation region 14 in the Y direction may be, for example, the minimum fabrication dimension F.

Next, the second element isolation regions 17A to 17C are formed extending in the Y direction in the main surface 13a of the semiconductor substrate 13 using the same techniques used to form the first element isolation regions 14.

When forming the second element isolation region 17A to 17C, a plurality of the second element isolation regions 17A to 17C is formed in the X direction with a predetermined interval therebetween. The top surface of the plurality of second element isolation regions 17A to 17C is formed flush with the main surface 13a of the semiconductor substrate 13.

The depth of the second element isolation regions 17A to 17C from the main surface 13a of the semiconductor substrate 13 may be 250 nm, for example. Additionally, the width of the second element isolation regions 17A to 17C in the Y direction may be for example the minimum fabrication dimension F.

Hereby, the active region 19-1 (active region 19), which is compartmentalized by the plurality of first element isolation regions 14 and second element isolation regions 17A to 17C, is formed in the X direction and the Y direction.

When formed, the active region 19-1 includes a first horizontal active region segment 81 extending in the X direction and constituting one end of the active region 19-1 in the X direction, a second horizontal active region segment 82 extending in the X direction and constituting the other end of the active region 19-1 in the X direction, and a sloped active region segment 83 arranged between the first horizontal active region segment 81 and the second horizontal region active region segment 82, and extending in the X1 direction.

The width of an active region 19 in the Y direction may be, for example, the minimum fabrication dimension F.

Subsequently, the first through fourth trenches 23 to 26 are formed in the main surface 13a of the semiconductor substrate 13 using known techniques; the first through fourth trenches 23 to 26 extend in the Y direction and partition the active region 19 into five equal segments. When formed, the first through fourth trenches 23 to 26 extend over the plurality of active regions 19-1 arranged in the Y direction, and the plurality of first element isolation regions 14.

Hereby, the first through fourth trenches 23 to 26 partition the plurality of first element isolation regions 14 arranged in the Y direction.

The depth of the first through fourth trenches 23 to 26 from the main surface 13a of the semiconductor substrate 13 may be shallower than the depth of the first and the second element isolation regions 14, and 17A to 17C. If the depth of the first and the second element isolation regions 14, and 17A to 17C is 250 nm, then the depth of the first through fourth trenches 23 to 26 may be, for example, 150 nm.

Next, the gate insulating film is formed with known techniques to cover the inner surfaces of the first through fourth trenches 23 to 26.

Subsequently, known techniques may used to simultaneously form and embed the first word line 89 in the lower portion of the first trench 23 via the gate insulating film 87, the second word line 95 in the lower portion of the second trench 24 via the gate insulating film 87, the third word line 98 in the lower portion of the third trench 25 via the gate insulating film 87, and the fourth word line 103 in the lower portion of the fourth trench 26 via the gate insulating film 87.

Next, the embedding insulating film 36 that embeds the upper portion of the first through fourth trenches 23 to 26 is formed with known techniques. Hereby, the embedding insulating film 36 covers the upper surface of the first through fourth word lines 89, 95, 98, and 103. The upper surface of the embedding insulating film 36 is flush with the main surface 13a of the semiconductor substrate 13.

As the embedding insulating film 36, a silicon nitride film (SiN film) may be used, for example.

Next, the main surface 13a of the semiconductor substrate 13 is doped with n-type impurities using ion implantation to simultaneously form the first capacitor impurity diffusion region 91, the second capacitor impurity diffusion region 93, the bit line impurity diffusion region 96, the third capacitor impurity diffusion region 101, and the fourth capacitor impurity diffusion region 105 in the active region 19-1.

When formed, the first capacitor impurity diffusion region 91 is formed in the first horizontal active region segment 81, which is located between the upper portion of the second element isolation region 17A adjoining the first trench 23, and the upper portion of the first trench 23. The second capacitor impurity diffusion region 93 is formed in the sloped active region segment 83, which is located between the upper portion of the first trench 23, and the upper portion of the second trench 24.

The bit line impurity diffusion region 96 is formed in the center of the sloped active region segment 83, located between the upper portion of the second trench 24 and the upper portion of the third trench 25. The third capacitor impurity diffusion region 101 is formed in the sloped active region segment 83, located between the upper portion of the third trench 25, and upper portion of the fourth trench 26.

The fourth capacitor impurity diffusion region 105 is formed in the second horizontal active region segment 82 located between the upper portion of the fourth trench 26, and the upper portion of the second element isolation region 17B.

The upper surfaces of the first capacitor impurity diffusion region 91, the second capacitor impurity diffusion region 93, the bit line impurity diffusion region 96, the third capacitor impurity diffusion region 101, and the fourth capacitor impurity diffusion region 105 respectively coincide with the main surface 13a of the semiconductor substrate.

The depth of the first capacitor impurity diffusion region 91, the second capacitor impurity diffusion region 93, the bit line impurity diffusion region 96, the third capacitor impurity diffusion region 101, and the fourth capacitor impurity diffusion region 105 from the main surface 13a of the semiconductor substrate 13 is, for example, 50 nm.

Next, forming the first capacitor impurity diffusion region 91, the second capacitor impurity diffusion region 93, the bit line impurity diffusion region 96, the third capacitor impurity diffusion region 101, and the fourth capacitor impurity diffusion region 105 thereby forms the first through fourth transistors 31 to 34.

The first transistor 31 is formed to include the gate insulating film 87, the first word line 89, the first capacitor impurity diffusion region 91, and the second capacitor impurity diffusion region 93.

The second transistor 32 is formed to include the gate insulating film 87, the second word line 95, the second capacitor impurity diffusion region 93, and the bit line impurity diffusion region 96.

The third transistor 33 is formed to include the gate insulating film 87, the third word line 98, the bit line impurity diffusion region 96, and the third capacitor impurity diffusion region 101.

The fourth transistor 34 is formed to include the gate insulating film 87, the fourth word line 103, the third capacitor impurity diffusion region 101, and the fourth capacitor impurity diffusion region 105.

The first through fourth transistors 31 to 34 are structured such that the first through fourth word lines 89, 95, 98, and 103 (gate electrodes) are embedded in the semiconductor substrate 13, thereby forming three dimensional channel regions in the semiconductor substrate 13 which configure the bottom and side surfaces of the first through fourth trenches 23 to 26 in the active region 19-1.

In this manner, the channel regions formed by the first through fourth transistors 31 to 34 are three dimensional, thereby making it possible to increase the effective channel length thereof compared to the well-known planar transistor, and thereby preventing the short channel effect.

Additionally, preventing the short channel effect thereby allows for further advances in the microfabrication of the first through fourth transistors 31 to 34.

Next, the interlayer insulating film 38 for bit line contact formation having a bit line contact opening 107 is formed on the upper surfaces of the first element isolation region 14, the embedding insulating film 36, and the second element isolation regions 17A to 17C respectively, using known techniques.

As the base material for the interlayer insulating film 38 for bit line contact formation, a silicon oxide film (SiO₂) may be used for example. The bit line contact opening 107 is formed to expose the upper surface of the bit line impurity diffusion region 96.

Next, using known techniques, a conductive film is deposited covering the upper surface of the interlayer insulating film 38 for bit line contact formation with a thickness sufficient to embed the bit line contact opening 107. A silicon nitride film (SiN film) may be deposited using known techniques to become the base material for the cap insulating film 45.

Subsequently, the silicon nitride film (SiN film) may be patterned using photolithography or dry etching to form the cap insulating film 45.

The above described conductive film may be patterned using anisotropic etching with the cap insulating film 45 as an etching mask to simultaneously form the bit line contact plug arranged inside the bit line contact opening 107, and the bit line 43 integrated with the bit line contact plug 41.

Next, the sidewall 46 that covers the side surface of the bit line 43 and the side surface of the cap insulating film 45 may be formed using known techniques, and as the base material for the sidewall 46, a silicon nitride film (SiN film), for example, may be employed.

The interlayer insulating film 48 for capacitor contact formation that embeds the space created between the bit lines 43 via the sidewall 46 is then formed on the interlayer insulating film 38 for bit line contact formation. When formed, the upper surface of the interlayer insulating film 48 for capacitor contact formation is flush with the upper surface of the cap insulating film 45.

The interlayer insulating film 48 for capacitor contact formation may be a silicon oxide film (SiO₂) formed by CVD, or a coated insulating film (silicon oxide film, SiO₂) formed using the spin on glass (SOG) technique, or the like.

Subsequently, dry etching the interlayer insulating film 38 for bit line contact formation, and the interlayer insulating film 48 for capacitor contact formation using known techniques thereby forms the first through fourth capacitor contact holes 51 to 54.

At this time, the first capacitor contact hole 51 is formed to expose the upper surface of the first capacitor impurity diffusion region 91; further, the second capacitor contact hole 52 is formed to expose the upper surface of the second capacitor impurity diffusion region 93.

The third capacitor contact hole 53 is formed to expose the upper surface of the third capacitor impurity diffusion region 101; further, the fourth capacitor contact hole 54 is formed to expose the upper surface of the fourth capacitor impurity diffusion region 105.

Subsequently, known techniques may be used to simultaneously form and embed the first capacitor contact plug 61 in the first capacitor contact hole 51, the second capacitor contact plug 62 in the second capacitor contact hole 52, the third capacitor contact plug 63 in the third capacitor contact hole 53, and the fourth capacitor contact plug 64 in the fourth capacitor contact hole 54.

Hereby the lower end of the first capacitor contact plug 61 is in contact with the upper surface of the first capacitor impurity diffusion region 91, and the lower end of the second capacitor contact plug 62 is in contact with the upper surface of the second capacitor impurity diffusion region 93.

Further the lower end of the third capacitor contact plug 63 is in contact with the upper surface of the third capacitor impurity diffusion region 101, and the lower end of the fourth capacitor contact plug 64 is in contact with the upper surface of the fourth capacitor impurity diffusion region 105.

Next, lower electrodes 111 are respectively formed one each on the upper ends of the first through fourth capacitor contact plugs 61 to 64. The lower electrode 111 is crown shaped.

Next, a capacitor insulation film 112 is formed to cover the lower electrode 111 using a known technique. At this point, the capacitor insulation film 112 is formed to be thick enough to not bury the inner portions of the lower electrode 111.

An upper electrode 113 is then formed to cover the surface of the capacitor insulation film 112. The upper electrode 113 is formed thick enough to embed the inside of the lower electrode 111 and the space between the lower electrodes 111 via the capacitor insulation film 112. The upper surface of the upper electrode 113 is flat.

Hereby, the first capacitor 71 arranged on the first capacitor contact plug 61 and made from a lower electrode 111, a capacitor insulation film 112, and an upper electrode 113, the second second arranged on the second capacitor contact plug 62 and made from a lower electrode 111, a capacitor insulation film 112, and an upper electrode 113, the third capacitor 73 arranged on the third capacitor contact plug 63 and made from a lower electrode 111, a capacitor insulation film 112, and an upper electrode 113, and the fourth capacitor 74 arranged on the fourth capacitor contact plug 64 and made from a lower electrode 111, a capacitor insulation film 112, and an upper electrode are simultaneously formed.

Additionally, forming the first through fourth capacitors 71 to 74 thereby simultaneously forms the first memory cell MC1 made from the first transistor 31 and the first capacitor 71, the second memory cell MC2 made from the second transistor 32 and the second capacitor 72, the third memory cell MC3 made from the third transistor 33 and the third capacitor 73, and the fourth memory cell MC4 made from the fourth transistor 34 and the fourth capacitor 74.

A first memory cell unit 11 is thereby formed for the semiconductor device 10.

Moreover, an interlayer insulation film (not shown), a via part (not shown) that penetrates the interlayer insulation film, wiring (not shown) arranged on the interlayer insulation film and electrically connected with the via part, and the like may be formed on the upper surface of the upper electrode 113 illustrated in FIG. 2.

### Second Embodiment

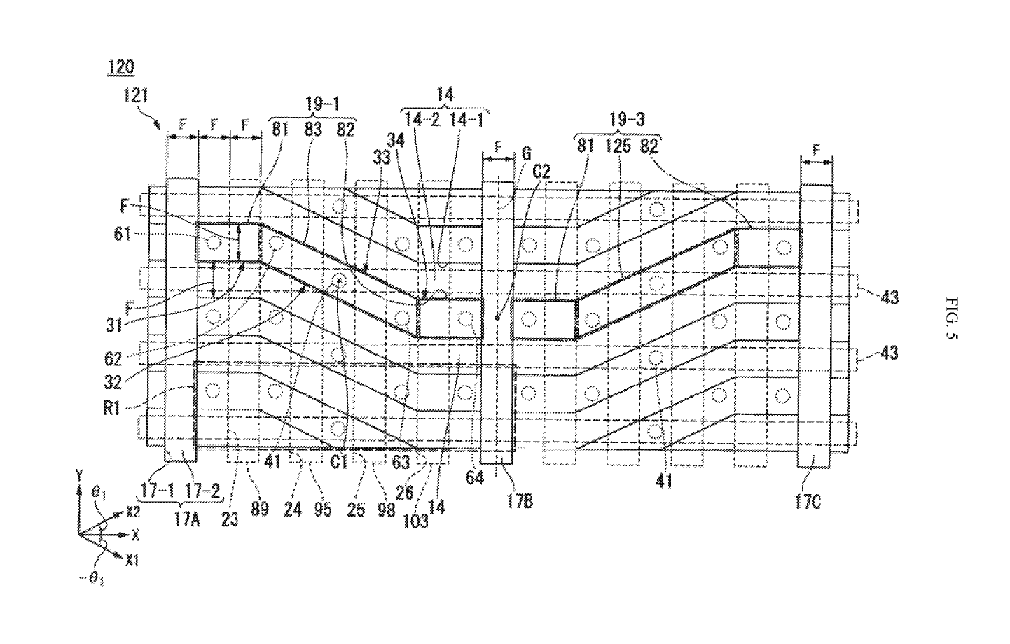

FIG. 5 is a plan view illustrating a portion of the constituent elements of a memory cell unit in a semiconductor device according to a second embodiment of the present invention. In FIG. 5, sections having the same configuration as the memory cell unit 11 in the semiconductor device 10 illustrated in FIG. 1 are given the same reference numerals.

Among the constituent elements of a memory cell unit 121, FIG. 5 shows only the first element isolation region 14, the second element isolation region 17A to 17C, the active regions 19-1 and 19-3 (unitary active regions), the first through fourth trenches 23 to 26, first through fourth transistors 31 to 34, the bit line contact plug 41, the bit line 43, the first through fourth capacitor contact plugs 61 to 64, the first horizontal active region segment 81, the second horizontal active region segment 82, the sloped active region segments 83 and 125, and the first through fourth word lines 89, 95, 98, and 103.

Referring FIG. 5, the memory cell unit 121 of the semiconductor device 120 of the second embodiment is configured similar to the memory cell unit 11 with the exception that the memory cell unit 121 includes an active region 19-3 instead of the active region 19-2 configuring the memory cell unit 11 of the semiconductor device 10 of the first embodiment illustrated in FIG. 1, and the shape of the first element isolation region 14 is a shape that can compartmentalize the active region 19-3.

That is, the memory cell unit 121 includes the active region 19-1 (one active region) and an active region 19-3 (the other active region) which are in contact so as to sandwich the second element isolation region 17B in the X direction.

The active region 19-3 is configured similar to the active region 19-2 with the exception that it has a sloped active region segment 125 instead of the sloped active region segment 83 which constitutes the active region 19-2 illustrated in FIG. 1.

The sloped active region segment 125 differs from the sloped active region segment 83 in that instead of extending in the X1 direction, the sloped active region segment 125 extends in the X2 direction. For example, if the angle formed between the X direction and the X1 direction is −θ1, the angle formed between the X direction and the X2 direction is θ1.

One end of the sloped active region segment 125 is integrated with the first horizontal active region segment 81, and the other end is integrated with the second horizontal active region segment 82.

The width of the sloped active region segment 125 in the X direction is equal to the width of the sloped active region segment 83 in the X direction, and for instance may be 5F (five times the minimum fabrication dimension).

The first horizontal active region segment 81 of the active region 19-3 sandwiches the second element isolation region 17B and is arranged to face the second horizontal active region segment 82 of the active region 19-1.

The active regions 19-1 and 19-3 pass the center point C2 of the second element isolation region 17B sandwiched between the first and the second horizontal active region segments 81 and 82. Additionally the active regions 19-1 and 19-3 are arranged so as to be symmetrical about a center line G of the second element isolation region extending in the Y direction.

The layout of the active regions 19-1 and 19-3 differs from that of the memory cell unit 11 described for the first embodiment.

The active regions 19-1 and 19-3 arranged in the above described layout are such that the second horizontal active region segment 82 constituting the active region 19-1, and the first horizontal active region segment 81 constituting the active region 19-3 are arranged along straight lines parallel to the X direction, and the first horizontal active region segment 81 constituting the active region 19-1 and the second horizontal active region segment 82 constituting the active region 19-3 are arranged along straight lines parallel to the X direction.

In the first embodiment, the active region group comprised of a plurality of active regions 19-1 and 19-2 is arranged to extend in the X1 direction as a whole; however in the second embodiment, the active region group comprised of a plurality of active regions 19-1 and 19-3 is arranged to repeatedly and alternately angle in the X1 direction and in the X direction while on the whole extending in the X direction.

The semiconductor device 120 of the second embodiment configured as above described provides the same effects as a semiconductor device 10 of the first embodiment.

### Third Embodiment

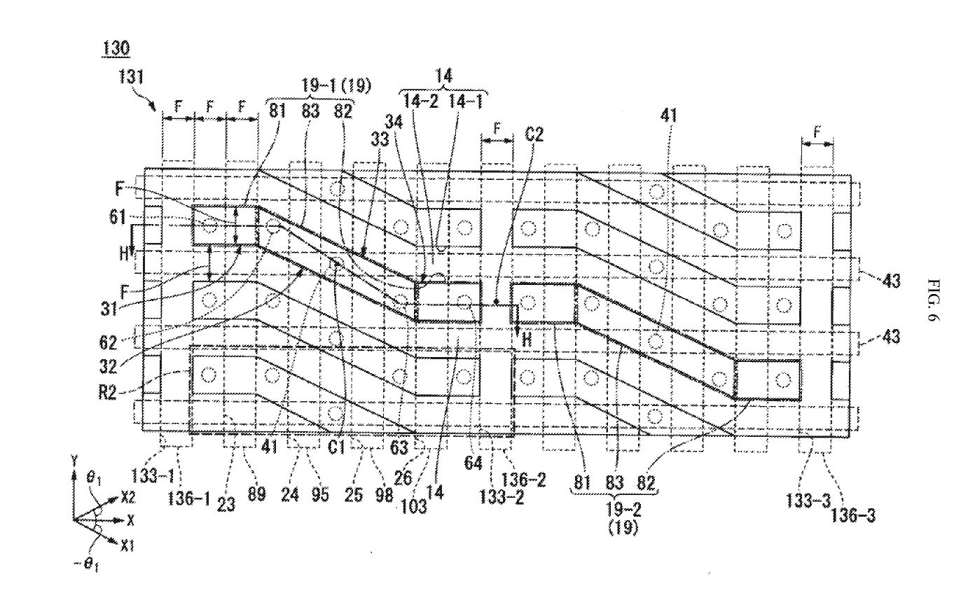

FIG. 6 is a plan view illustrating a portion of the constituent elements of a memory cell unit in a semiconductor device according to a third embodiment of the present invention. In FIG. 6, sections having the same configuration as the memory cell unit 11 in the semiconductor device 10 illustrated in FIG. 1 are given the same reference numerals.

Among the constituent elements of a memory cell unit 131, FIG. 6 shows only the first element isolation region 14, dummy gate trenches 133-1 to 133-3, dummy gate electrodes 136-1 to 136-3, the active regions 19, 19-1, and 19-2, the first through fourth trenches 23 to 26, the first through fourth transistors 31 to 34, the bit line contact plug 41, the bit line 43, the first through fourth capacitor contact plugs 61 to 64, the first horizontal active region segment 81, the second horizontal active region segment 82, the sloped active region segment 83, and the first through fourth word lines 89, 95, 98, and 103.

Additionally, the region defined by R2 shown in FIG. 6 illustrates a basic cell region (referred to as “basic cell region R2”), which includes four memory cells MC1 to MC4, and one bit line impurity diffusion region 96.

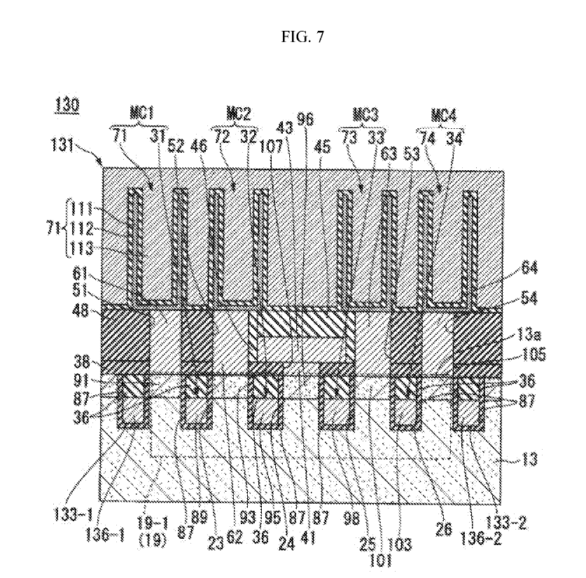

FIG. 7 is a cross-sectional view along the line H-H in the memory cell unit in the semiconductor device illustrated in FIG. 6. In FIG. 7, sections having the same configuration as the memory cell unit 131 in the semiconductor device 130 illustrated in FIG. 6 are given the same reference numerals. Furthermore, in FIG. 6 the region in which the channels for the first through fourth transistors 31 to 34 are formed are indicated by solid arrows.

FIG. 6 and FIG. 7 illustrate Dynamic Random Access Memory (DRAM) as one example of the semiconductor device 130 of the third embodiment.

Referring to FIG. 6 and FIG. 7, the memory cell unit 131 in the semiconductor device 130 of the third embodiment is configured similarly to the memory cell unit 11 with the exception that instead of the second element-isolation regions 17A to 17C provided in the memory cell unit 11 in the semiconductor device 10 of the first embodiment, the memory cell unit 131 is provided with dummy gate trenches 133-1 to 133-3, and dummy gate electrodes 136-1 to 136-3, which electrically isolate elements.

The dummy gate trench 133-1 is provided in a section corresponding the location where the second element isolation region 17A illustrated in FIG. 1 is formed. The dummy gate trench 133-1 partitions the plurality of first element isolation regions 14 arranged in the Y direction, and exposes the side surfaces of the first horizontal active region segments 81 in the plurality of active regions 19-1 arranged in the Y direction.

The dummy gate trench 133-2 is provided in a section corresponding the location where the second element isolation region 17B illustrated in FIG. 1 is formed.

The dummy gate trench 133-3 partitions the plurality of first element isolation regions 14 arranged in the Y direction and exposes the side surfaces of the second horizontal active region segments 82 in the plurality of active regions 19-2 arranged in the Y direction.

The dummy gate trench 133-3 is provided in a section corresponding the location where the second element isolation region 17C illustrated in FIG. 1 is formed.

The dummy gate trench 133-2 partitions the plurality of first element isolation regions 14 arranged in the Y direction and exposes the side surfaces of the second horizontal active region segments 82 in the plurality of active regions 19-1 arranged in the Y direction, and exposes the side surfaces of the first horizontal active region segments 81 in the plurality of active regions 19-2 arranged in the Y direction.

The depth of the dummy trenches 133-1 to 133-3 from the main surface 13a of the semiconductor substrate 13 may be the same as the depth of the first through fourth trenches 23 to 26.

In this manner, by configuring the dummy gate trenches 133-1 to 133-3 to have the same depth as the first through fourth trenches 23 to 26, the first to fourth trenches 23 to 26 and the dummy gate trenches 133-1 to 133-3 can be formed simultaneously.

Therefore there is no need for a separate process to form the dummy gate trenches 133-1 to 133-3.

The gate insulating film 87, which is of a thickness that does not embed the dummy gate trenches 133-1 to 133-3, is arranged on the inner surfaces of the dummy gate trenches 133-1-133-3.

The dummy gate electrode 136-1 is embedded in the lower portion of the dummy gate trench 133-1 via the gate insulating film 87. The dummy gate electrode 136-2 is embedded in the lower portion of the dummy gate trench 133-2 via the gate insulating film 87.

The dummy gate electrode 136-3 is embedded in the lower portion of the dummy gate trench 133-3 via the gate insulating film 87.

A voltage applied to the dummy gate electrodes 136-1 to 136-3 is different from the voltage applied to the first through fourth word lines 89, 95, 98, and 103. More specifically, a voltage of zero or a negative voltage is applied to the dummy gate electrodes 136-1 to 136-3 to prevent a channel region from forming on the main surface 13a of the semiconductor substrate 13.

The conductive film used as the base material for forming the first through fourth word lines 89, 95, 98, and 103, for example, may be used as the base material for the dummy gate electrodes 136-1 to 136-3.

In this manner, using the same conductive film used as the base material for forming the first through fourth word lines 89, 95, 98, and 103 as the base material for the dummy gate electrodes 136-1 to 136-3 thereby allows the dummy gate electrodes 136-1 to 136-3 and the first through fourth word lines 89, 95, 98, and 103 to be formed simultaneously.

Consequently, there is no need for a separate process to form dummy gate electrode 136-1 to 136-3.

The upper portion of the first through fourth dummy gate trenches 133-1 to 133-4 is embedded in the embedding insulating film 36. The upper surface of the embedded insulation film 36 is flush with the main surface 13a of the semiconductor substrate 13.

If, in the above configured semiconductor device 130, the respective widths of the dummy gate trenches 133-1 to 133-3 in the X direction, the first through fourth capacitive impurity diffusion regions 91, 93, 101, and 105 in the X direction, the bit line impurity diffusion region 96 in the X direction, the first through fourth word lines 89, 95, 98, and 103 in the X direction, the first element isolation region 14 in the Y direction, and the active region 19-1 in the Y direction is the minimum fabrication dimension F, then the respective widths of the first horizontal active region segment 81 in the X direction and the second horizontal active region segment 82 in the X direction are 2F, and the width of the slope active region segment 83 in the X direction is 5F.

Accordingly, the total width of the first through fourth capacitor impurity diffusion regions 91, 93, 101, and 105, the bit line impurity diffusion region 96, the first through fourth word lines 89, 95, 98, and 103, and the dummy gate trench 133-2, each in the X direction, is 10F.

That is, the width of a basic cell region R2 including the four memory cells MC1 to MC4, and a single bit line impurity diffusion region 96 in the X direction is 10F, and in the Y direction is 2F. Accordingly, the area of the basic cell region R2 is 20F².

The semiconductor device 130 according to the third embodiment is configured such that the first through fourth trenches 23 to 26, and the first through fourth dummy gate trenches 133-1 to 133-4 are systematically aligned, and therefore using photolithography, it is possible to minimize optical proximity effects when processing the resist mask used for dry etching the first through fourth trenches 23 to 26 and the first through fourth dummy gate trenches 133-1 to 133-4.

This also improves precision when fabricating the first through fourth trenches 23 to 26 and the first through fourth dummy gate trenches 133-1 to 133-4.

The semiconductor device 130 of the third embodiment configured as above described provides the same effects as a semiconductor device 10 of the first embodiment.

While preferred embodiments of the present invention have been described, the present invention is not limited to the specific embodiments described herein, and may be modified in various ways insofar as the modifications are within the scope of the claims which describe the present invention.

### INDUSTRIAL APPLICABILITY

The present invention may be adopted in semiconductor devices.

### REFERENCE NUMERALS

10, 120, 130: Semiconductor device
11, 121, 131: Memory cell unit
13: Semiconductor substrate
13a: Main surface
14: First element isolation region
14-1: First element isolation trench
14-2: First element isolation insulating film
17A to 17C: Second element isolation region
17-1: Second element isolation trench
17-2: Second element isolation insulating film
19, 19-1, 19-2, 19-3: Active region
23: First trench
24: Second trench
25: Third trench
26: Fourth trench
31: First transistor
32: Second transistor
33: Third transistor
34: Fourth transistor
36: Embedding insulating film
38: Interlayer insulating film for bit line contact formation
41: Bit line contact plug
43: Bit line
45: Cap insulating film
46: Sidewall
48: Interlayer insulating film for capacitor contact formation
51: First capacitor contact hole
52: Second capacitor contact hole
53: Third capacitor contact hole
54: Fourth capacitor contact hole
61: First capacitor contact plug
62: Second capacitor contact plug
63: Third capacitor contact plug
64: Fourth capacitor contact plug
71: First capacitor
72: Second capacitor
73: Third capacitor
74: Fourth capacitor
81: First horizontal active region segment
82: Second horizontal active region segment
83, 125: Sloped active region segment
87: Gate insulating film
89: First word line
91: First capacitor impurity diffusion region
93: Second capacitor impurity diffusion region
95: Second word line
96: Bit line impurity diffusion region
98: Third word line
101: Third capacitor impurity diffusion region
103: Fourth word line
105: Fourth capacitor impurity diffusion region
107: Bit line contact opening
111: Lower electrode
112: Capacitance insulating film
113: Upper electrode
133-1 to 133-3: Dummy gate trench
136-1 to 136-3: Dummy gate electrode
C1, C2: Center point
G: Center line
MC1: First memory cell
MC2: Second memory cell
MC3: Third memory cell
MC4: Fourth memory cell
R1, R2: Basic cell region
θ1, −θ1: Angle

1. A semiconductor device comprising:
a bit line extending in a straight line in a first direction on a semiconductor substrate;
an active region having a bit line impurity diffusion region electrically connected to the bit line and arranged at the center of the active region; and
a plurality of word lines extending in a second direction orthogonal to the first direction to separate the upper portion of the active region into five segments;
wherein the active region includes:
a first horizontal active region segment extending in the first direction and constituting one end of the active region;
a second horizontal active region segment extending in the first direction and constituting another end of the active region; and
a sloped active region segment arranged between the first and second horizontal active region segments extending in a direction inclined with respect to the first direction, and connecting the first and second horizontal active region segments; and
wherein one word line is arranged in each of the first horizontal active region segment and the second horizontal active region segment, and two word lines are further arranged in the sloped active region segment with the bit line impurity diffusion region interposed therebetween.

2. The semiconductor device according to claim 1, wherein the bit line impurity diffusion region is arranged in the center of the sloped active region segment, and the active region is symmetrical about a center point in the sloped active region segment.

3. The semiconductor device according to claim 1, wherein the bit line passes above the center point of the sloped active region segment.

4. The semiconductor device according to claim 1, further comprising:
a plurality of element isolation regions extending in the second direction on the main surface of the semiconductor substrate, and arranged along the first direction to come into contact with two active regions in the first direction;
the second horizontal active region segment of one of the two active regions sandwiches an element isolation region and is arranged to face the first horizontal active region segment of another active region; and
the one active region and the other active region are arranged to be symmetrical about a center point in a section of the element isolation region interposed between the first and the second horizontal active region segments.

5. The semiconductor device according claim 1, further comprising:
a plurality of element isolation regions extending in the second direction on the main surface of the semiconductor substrate, and arranged along a first direction to come into contact with two active regions in the first direction;
the second horizontal active region segment of one of the two active regions sandwiches an element isolation region and is arranged to face the first horizontal active region segment of another active region; and
the one active region and the other active region pass the center point of the element isolation region interposed between the first and the second horizontal active region segments, and are arranged to be line symmetrical about a center line of the element isolation region that extends in the second direction.

6. The semiconductor device according to claim 1, further comprising:
a first trench provided in the first horizontal active region segment and extending in the second direction;
a second and a third trench provided in the sloped active region segment and extending in the second direction;
a fourth trench provided in the second horizontal active region segment and extending in the second direction; and
a gate insulating film that covers the inner surfaces of the first through fourth trenches;
wherein the plurality of word lines includes a first word line embedded in the lower portion of the first trench via the gate insulating film, a second word line embedded in the lower portion of the second trench via the gate insulating film, a third word line embedded in the lower portion of the third trench via the gate insulating film, and a fourth word line embedded in the lower portion of the fourth trench via the gate insulating film.

7. The semiconductor device according to claim 6, further comprising:
a first transistor as a constituent element of the first word line;
a second transistor as a constituent element of the second word line;
a third transistor as a constituent element of the third word line; and
a fourth transistor as a constituent element of the fourth word line.

8. The semiconductor device according to claim 7, further comprising:
a first capacitor impurity diffusion region arranged in the first horizontal active region segment located between the upper portion of the first trench and the upper portion of the element isolation region adjacent to the first trench;
a second capacitor impurity diffusion region arranged in the sloped active region segment located between the upper portion of the first trench and the upper portion of the second trench;
a bit line impurity diffusion region arranged in the sloped active region segment located between the upper portion of the second trench and the upper portion of the third trench;
a third capacitor impurity diffusion region arranged in the sloped active region segment located between the upper portion of the third trench and the upper portion of the fourth trench; and
a fourth capacitor impurity diffusion region arranged in the second horizontal active region segment located between the upper portion of the fourth trench and the upper portion of the element isolation region adjacent to the fourth trench;
wherein:
the second capacitor impurity diffusion region functions as an impurity diffusion region shared between the first and the second transistor;
the bit line impurity diffusion region functions as an impurity diffusion region shared between the second and the third transistor; and
the third capacitor impurity diffusion region functions as an impurity diffusion region shared between the third and the fourth transistor.

9. The semiconductor device according to claim 4, wherein instead of the element isolation region, a dummy gate trench is provided on the main surface of the semiconductor substrate extending in the second direction, and a dummy gate electrode is provided embedded in the lower portion of the dummy gate trench.

10. The semiconductor device according to claim 4, further comprising a plurality of other element isolation regions that define the boundaries between the active regions arranged in the second direction.

11. The semiconductor device according to claim 1, further comprising a bit line contact plug arranged between the bit line and the bit line impurity diffusion region and electrically connecting the bit line and the bit line impurity diffusion region.

12. The semiconductor device according to claim 8, further comprising:
a first capacitor contact plug arranged on the first capacitor impurity diffusion region;
a second capacitor contact plug arranged on the second capacitor impurity diffusion region;
a third capacitor contact plug arranged on the third capacitor impurity diffusion region; and
a fourth capacitor contact plug arranged on the fourth capacitor impurity diffusion region;
wherein the upper end surfaces of the first through fourth capacitor contact plugs are arranged above the upper surface of the bit line.

13. The semiconductor device according to claim 12, further comprising:
a first capacitor arranged on the first capacitor contact plug;
a second capacitor arranged on the second capacitor contact plug;
a third capacitor arranged on the third capacitor contact plug; and
a fourth capacitor arranged on the fourth capacitor contact plug.

14. The semiconductor device according to claim 10, wherein the width of the element isolation region in the first direction, the width of the first through fourth capacitor impurity diffusion regions in the first direction, the width of the first through fourth word lines in the first direction, the width of the active region in the second direction, and the width of the other element isolation regions in the second direction are a minimum fabrication dimension, F.

15. The semiconductor device according to claim 10, wherein the width of the dummy gate trench in the first direction, the width of the first through fourth capacitor impurity diffusion regions in the first direction, the width of the first through fourth word lines in the first direction, the width of the active region in the second direction, and the width of the other element isolation regions in the second direction are a minimum fabrication dimension, F.
